(19) United States
(12) Patent Application Publication
(10) Pub. No.: US 2017/0186586 A1
(43) Pub. Date: Jun. 29, 2017

(54) PLASMA SYSTEM, PLASMA PROCESSING METHOD, AND PLASMA ETCHING METHOD

(71) Applicant: Samsung Electronics Co., Ltd., Suwon-si (KR)

(72) Inventors: Sejin Oh, Hwaseong-si (KR); Je-Hun Woo, Suwon-si (KR); Chungho Cho, Suwon-si (KR); Dougyong Sung, Seoul (KR); Jang Gyoo Yang, Seongnam-si (KR); Jaechul Jung, Seoul (KR)

(21) Appl. No.: 15/352,952

(22) Filed: Nov. 16, 2016

(30) Foreign Application Priority Data
Dec. 23, 2015 (KR) 1020150185181

(51) Int. Cl. H01J 37/32; H01L 21/67; H01L 21/3065

(52) U.S. Cl. CPC H01J 37/32146; H01L 21/3065; H01L 21/67069; H01J 37/32128; H01J 37/3244; H01J 2237/334

(57) ABSTRACT

A plasma system includes a source electrode, an RF source power generation unit, an RF source power output unit, and a source power output managing unit. The source power output managing unit determines an amplitude and a duty cycle of a pulse RF source power based on information on an amplitude of a continuous wave RF source power.

### CROSS-REFERENCE TO RELATED APPLICATIONS

This U.S. non-provisional patent application claims priority under 35 U.S.C. §119 to Korean Patent Application No. 10-2015-0185181, filed on Dec. 23, 2015, in the Korean Intellectual Property Office, the contents of which are herein incorporated by reference in their entirety.

### BACKGROUND

Example embodiments of the present inventive concepts relate to a system for and a method of fabricating a semiconductor device. More particularly, example embodiments of the present inventive concepts relate to a plasma-etching system and a plasma-etching method.

Generally, several unit processes are performed to fabricate a semiconductor device. The unit processes generally include a deposition process, a photolithography process, an etching process, an ion implantation process, and an ashing process. The etching process may be classified into a dry etching process and a wet etching process. The dry etching process may be mainly performed using plasma including radicals and ions. A radio frequency (RF) power may be used to produce the radicals and ions from a reaction gas that is supplied into a chamber.

### SUMMARY

Some embodiments of the inventive concepts provide a plasma system configured to allow an etching rate in an etching process using a pulse plasma to be the same as that in an etching process using a continuous wave plasma.

Some embodiments of the inventive concepts provide a plasma processing method capable of preventing or suppressing a non-target layer from being damaged by an ion bombardment phenomenon.

According to an aspect of the inventive concepts, a plasma system may include a source electrode configured to generate plasma in a housing, a radio frequency (RF) source power generation unit configured to generate an RF source power to be provided to the source electrode, an RF source power output unit connected between the source electrode and the RF source power generation unit, the RF source power output unit configured to convert the RF source power to one of a first and second RF source power in response to a first output control signal, and to output the one of the first and second RF source power to the source electrode, and a source power output managing unit configured to determine an amplitude and a duty cycle of the second RF source power based on information on an amplitude of the first RF source power and to apply the first output control signal, which is used to output the second RF source power according to the determined amplitude and the determined duty cycle, to the RF source power output unit.

According to an aspect of the inventive concepts, a plasma system may include a source electrode configured to generate plasma in a housing, an RF power generation unit configured to generate an RF source power to be provided to the source electrode, a power mode selection unit connected between the RF power generation unit and the source electrode, the power mode selection unit configured to select whether to convert the RF source power to one of a first and second RF source power in response to a first control signal, an RF source power output unit connected between the power mode selection unit and the source electrode, the RF source power output unit configured to convert the RF source power to the one of the first and second RF source power and to output the one of the first and second RF source power to the source electrode in response to a second control signal, and a source power output managing unit configured to apply, to the power mode selection unit, the first control signal for determining the one of the first and second RF source power to be applied to the source electrode, to determine an amplitude and a duty cycle of the second RF source power based on information on an amplitude of the first RF source power, and to apply, to the RF source power output unit, the second control signal for outputting the second RF source power based on the determined amplitude and the determined duty cycle.

According to an aspect of the inventive concepts, a plasma processing method may include outputting a first RF source power to a source electrode to generate a continuous wave plasma in a housing, obtaining an etching rate of a layer from an input signal, which contains information on an etching time and a thickness of the layer, which is etched by a radical and an ion of the continuous wave plasma, and on a recombination time of the ion, calculating an amplitude and a duty cycle of a second RF source power, based on information on the first RF source power whose amplitude is proportional to the etching rate, and applying, to the source electrode, the second RF source power having the calculated amplitude and the calculated duty cycle, to generate a pulse plasma reaction and to etch a layer.

According to an aspect of the inventive concepts, a plasma system may include a chamber unit including a housing, a source electrode on the housing, and a bias electrode on an inner, bottom surface of the housing, a reaction gas supply unit configured to supply a reaction gas into the housing, and an RF source power supply unit connected to the source electrode, the RF source power configured to apply an RF source power to the reaction gas to generate plasma in the housing. The RF source power supply unit may include an RF source power generation unit configured to generate the RF source power, an RF source power output unit connected between the source electrode and the RF source power generation unit, the RF source power output unit configured to convert the RF source power to one of a first and second RF source power in response to a first output control signal and to output the one of the first and second RF source power to the source electrode, and a source power output managing unit configured to determine an amplitude and a duty cycle of the second RF source power based on information on an amplitude of the first RF source power and to apply the first output control signal, which is used to output the second RF source power according to the determined amplitude and the determined duty cycle, to the RF source power output unit.

In some embodiments, an end-point detector is configured to detect an end point of an etching process, in which a layer is etched using the plasma. The source power output managing unit receives a feedback input signal and a layer thickness signal from the end-point detector and calculates an etching rate of the layer, and the feedback input signal contains information on the end point of the etching process and the layer thickness signal contains information on a thickness of the layer.

According to an aspect of the inventive concepts, a plasma system may include a source electrode configured to generate plasma in a housing, an RF source power generation unit configured to generate an RF source power to be provided to the source electrode, a pulse RF source power output unit connected between the source electrode and the RF source power generation unit, the pulse RF source power output unit configured to convert the RF source power to a pulse RF source power in response to a first control signal and to output the pulse RF source power to the source electrode, and a source power output managing unit configured to apply, to the pulse RF source power output unit, the first control signal for adjusting a pulsing cycle of the pulse RF source power such that the pulsing cycle is shorter than a lifetime of a radical of the plasma and is longer than a lifetime of an ion of the plasma.

According to an aspect of the inventive concepts, a plasma processing method may include providing a substrate, on which a non-target structure and an etch target layer are sequentially stacked, in a housing, and inducing a pulse plasma from a reaction gas supplied on the non-target structure and etching the etch target layer using the pulse plasma. The pulse plasma may be induced to have a pulse period that is shorter than a lifetime of a radical of the reaction gas and is longer than a lifetime of ions of the reaction gas.

According to an aspect of the inventive concepts, a plasma system includes a chamber unit including a housing, a source electrode, and a bias electrode, an RF source power supply unit connected to the source electrode, the RF source power supply unit configured to apply an RF source power to the reaction gas to generate plasma in the housing, and an RF bias power supply unit controlled by the source power output managing unit, the RF bias power supply unit configured to supply an RF bias power to the bias electrode. The RF source power supply unit includes the RF source power output unit which is configured to convert the RF source power to one of a first and second RF source power in response to a first output control signal and to output the one of the first and second RF source power to the source electrode, and a source power output managing unit configured to determine an amplitude and a duty cycle of the second RF source power based on information on an amplitude of the first RF source power and to apply the first output control signal, which is used to output the second RF source power according to the determined amplitude and the determined duty cycle, to the RF source power output unit.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIG. 1 is a diagram illustrating a plasma system according to some embodiments of the inventive concepts.

FIG. 2 is graphs illustrating an RF source power of FIG. 1.

FIG. 3 is graphs illustrating an RF bias power of FIG. 1.

FIG. 4 is graphs illustrating a continuous wave (CW) RF source power and a CW RF bias power of FIGS. 2 and 3.

FIG. 5 is a graph illustrating a pulse RF source power and a pulse RF bias power of FIGS. 2 and 3.

FIG. 6 is a cross-sectional view illustrating a substrate and plasma of FIG. 1.

FIG. 7 is a block diagram illustrating an RF source power supply unit and an RF bias power supply unit of FIG. 1 according to some embodiments of the inventive concepts.

FIG. 8 is a block diagram illustrating a second RF source power output unit of FIG. 7 according to some embodiments of the inventive concepts.

FIG. 9 is a flow chart illustrating a plasma processing method of the source power output managing unit of FIG. 7 according to some embodiments of the inventive concepts.

FIG. 10 is graphs illustrating an energy of a CW RF source power and an energy of a pulse RF source power that have the same etching rate with respect to an etch target layer.

FIG. 11 is graphs illustrating a pulsing frequency of a pulse RF source power in FIG. 10.

FIG. 12 is a cross-sectional view illustrating a bombardment phenomenon of ions.

FIG. 13 is a graph illustrating a relationship between an etching rate of an etch target layer and a pulse RF source power of FIG. 10.

FIG. 14 is a graph illustrating a relationship between an etching rate of a non-target structure and a pulsing frequency of a pulse RF bias power of FIG. 11.

FIG. 15 is a flow chart illustrating a plasma etching method, which may be performed using a plasma system of FIG. 1 according to some embodiments of the inventive concepts.

### DETAILED DESCRIPTION

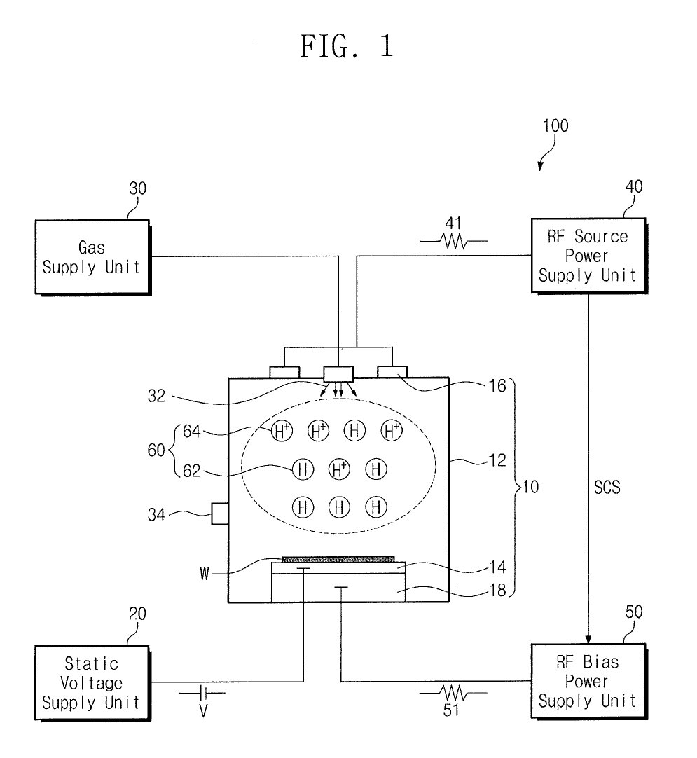

FIG. 1 is a diagram illustrating a plasma system 100 according to some embodiments of the inventive concepts.

Referring to FIG. 1, the plasma system 100 may include, for example, an inductively-coupled plasma (ICP) etching system. Alternatively, the plasma system 100 may include, for example, a capacitively-coupled plasma (CCP) etching system, a physical vapor deposition system, or a chemical vapor deposition system. In some embodiments, the plasma system 100 may include a chamber unit 10, a constant voltage supply unit 20, that is, a static voltage supply unit, a gas supply unit 30, an end-point detector 34, a radio frequency (RF) source power supply unit 40, and an RF bias power supply unit 50. A substrate W may be provided in the chamber unit 10. The constant voltage supply unit 20 may provide a constant voltage V to the chamber unit 10. The substrate W may be fastened to the chamber unit 10 using the constant voltage V.

The gas supply unit 30 may be configured to supply a reaction gas 32 into the chamber unit 10. For example, the gas supply unit may supply the reaction gas 32 though an input or opening in the chamber unit 10. The reaction gas 32 may be supplied onto the substrate W. The RF source power supply unit 40 may be configured to apply an RF source power 41 to the chamber unit 10. The RF source power 41 may be configured to generate plasma 60 from the reaction gas 32. The plasma 60 may be used to activate the reaction gas 32 and thereby to allow the reaction gas 32 to have higher reactivity. The RF bias power supply unit 50 may be configured to apply an RF bias power 51 to the chamber unit 10. The RF bias power 51 may be applied to allow the plasma 60 to be concentrated within a region on or over the substrate W. The plasma 60 may be used to etch the substrate W in a dry-etching manner. The end-point detector 34 may be used to detect a process end point for an etching process on the substrate W. Thus, damage to a non-etch target layer under a target layer may be minimized.

The chamber unit 10 may include, for example, a housing 12, an electrostatic chuck 14, a source electrode 16, and a bias electrode 18. The substrate W may be provided in the housing 12. The housing 12 may be provided to enclose the electrostatic chuck 14 and the bias electrode 18. The electrostatic chuck 14 may be disposed on an inner, bottom surface of the housing 12. The electrostatic chuck 14 may be configured to allow the substrate W to be loaded thereon. The source electrode 16 may be provided over the substrate W. For example, the source electrode 16 may be provided on the housing 12. In some embodiments, the source electrode 16 may be disposed in the housing 12. That is, the source electrode 16 may be disposed on an upper surface of the housing 12. The source electrode 16 may include a plurality of source electrodes. For example, the source electrode 16 may be disposed around the input for the reaction gas 32. The substrate W may be spaced apart from vertical sidewalls of the housing 12. Sidewalls of the electrostatic chuck 14 and the source electrode may extend beyond sidewalls of the substrate W in a substantially horizontal direction. The bias electrode 18 may be provided between the housing 12 and the electrostatic chuck 14.

The constant voltage supply unit 20 may be connected to the electrostatic chuck 14. The substrate W may be fastened to the electrostatic chuck 14 by the constant voltage supplied from the constant voltage supply unit 20. In some embodiments, the constant voltage supply unit 20 may be configured to generate a constant voltage of about 10-1000 V and supply the constant voltage to the electrostatic chuck 14. The RF bias power 51 may be applied to bias electrode 18.

The gas supply unit 30 may be configured to supply the reaction gas 32 into the housing 12. The reaction gas 32 may be used to etch the substrate W. In some embodiments, the reaction gas 32 may include, for example, hydrogen gas (H₂). In some embodiments, the reaction gas 32 may include, for example, hydrocarbon compounds, for example, methane (CH₄).

The RF source power supply unit 40 may be connected to the source electrode 16. The RF source power supply unit 40 may be configured to apply an RF source power 41 to the source electrode 16. The RF source power 41 applied to the source electrode 16 may be used to generate the plasma 60 from the reaction gas 32. In some embodiments, the RF source power 41 may have a frequency of, for example, about 13.5 MHz.

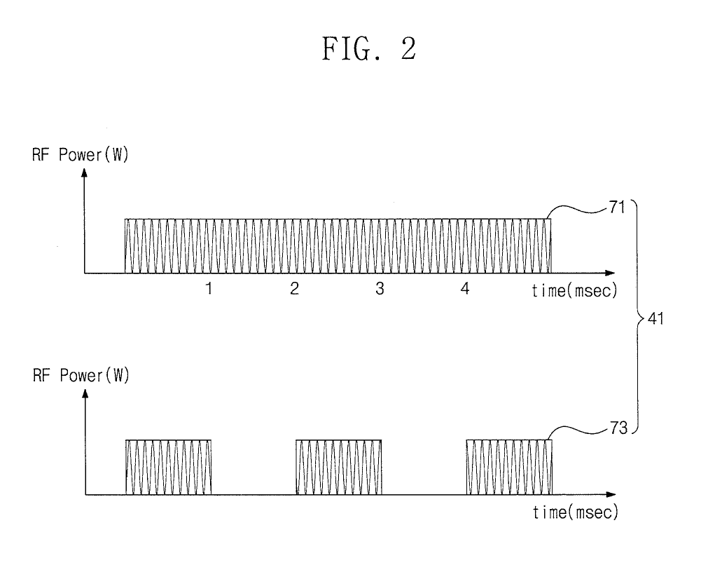

FIG. 2 is graphs illustrating an example of the RF source power 41 of FIG. 1.

Referring to FIG. 2, the RF source power 41 may include a continuous wave (CW) RF source power 71 and a pulse RF source power 73. Horizontal axes of the graphs of FIG. 2 represent a process time (in msec), and vertical axes of the graphs of FIG. 2 represent an intensity or amplitude of an RF power (in W). The intensity or amplitude of the CW RF source power 71 may be constant over time. The intensity or amplitude of the pulse RF source power 73 may be changed over time. For example, the pulse RF source power 73 may be applied with a pulsating intensity within a given period of time.

Referring to FIGS. 1 and 2, the CW RF source power 71 may be applied to the housing 12 through the source electrode 16 to generate plasma in the housing 12. The term ‘CW plasma’ may be used to refer to plasma generated by the CW RF source power 71. The pulse RF source power 73 may also be used to generate plasma in the housing 12. The term ‘pulse plasma’ may be used to refer to plasma generated by the pulse RF source power 73.

Referring to FIG. 1, the RF bias power supply unit 50 may be connected to the bias electrode 18. The RF bias power supply unit 50 may be configured to apply the RF bias power 51 to the bias electrode 18. The bias electrode 18 may be used to concentrate the plasma 60 within a region on or over the substrate W. For example, the RF bias power 51 may have a frequency of about 13.5 MHz.

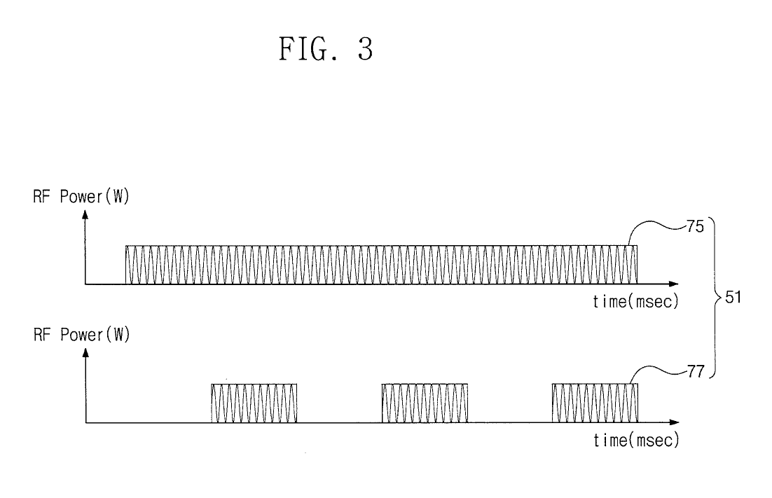

FIG. 3 is graphs illustrating an example of the RF bias power 51 of FIG. 1. Horizontal axes of the graphs of FIG. 3 represent a process time (in msec), and vertical axes of the graphs of FIG. 3 represent an intensity or amplitude of an RF power (in W).

Referring to FIG. 3, the RF bias power 51 may include a CW RF bias power 75 and a pulse RF bias power 77. The intensity or amplitude of the CW RF bias power 75 may be constant over time. The pulse RF bias power 77 may be changed over time, that is may be applied with a pulsating intensity within a given period of time.

Referring to FIG. 1, the RF bias power supply unit 50 may be connected to the RF source power supply unit 40. In some embodiments, the RF source power supply unit 40 may be configured to output a synchronizing control signal SCS to the RF bias power supply unit 50. The synchronizing control signal SCS may be used to simultaneously apply the RF source power 41 to the source electrode 16 and the RF bias power 51 to the bias electrode 18.

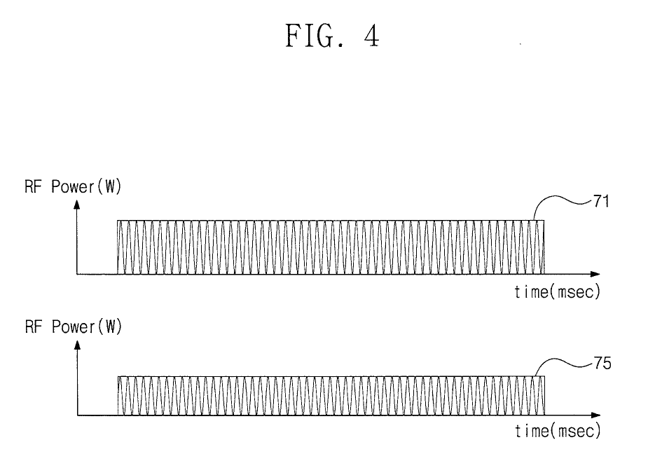

FIG. 4 is graphs illustrating the CW RF source power 71 of FIG. 2 and the CW RF bias power 75 of FIG. 3. Horizontal axes of the graphs of FIG. 4 represent a process time (in msec), and vertical axes of the graphs of FIG. 4 represent an intensity or amplitude of an RF power (in W).

Referring to FIGS. 1 and 4, when the CW RF source power 71 is applied to the source electrode 16 from the RF source power supply unit 40, the CW RF bias power 75 may be applied to the bias electrode 18 from the RF bias power supply unit 50. The CW RF source power 71 and the CW RF bias power 75 may be applied at substantially the same time to the source electrode 16 and the bias electrode 18, respectively. The CW RF source power 71 and the CW RF bias power 75 may be generated to have different amplitudes from each other. For example, the amplitude of the CW RF source power 71 may be greater than the amplitude of the CW RF bias power 75.

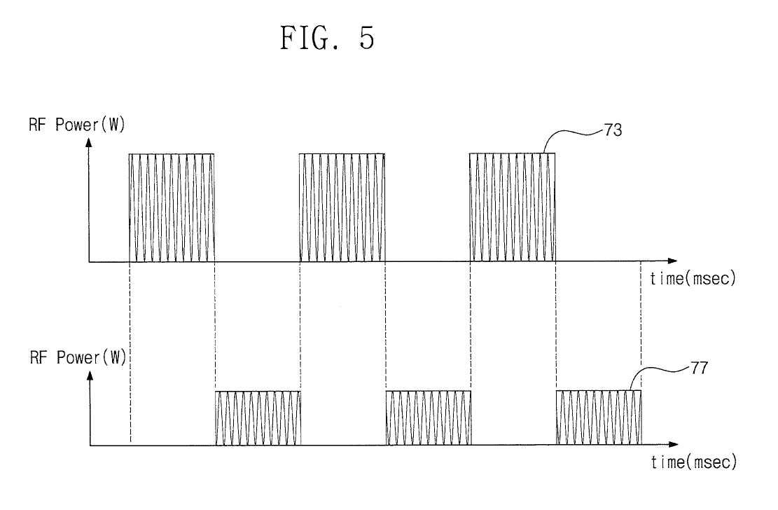

FIG. 5 is graphs illustrating the pulse RF source power 73 of FIG. 2 and the pulse RF bias power 77 of FIG. 3. Horizontal axes of the graphs of FIG. 5 represent a process time (in msec), and vertical axes of the graphs of FIG. 5 represent an intensity or amplitude of an RF power (in W).

Referring to FIGS. 1 and 5, when the pulse RF source power 73 is applied to the source electrode 16 from the RF source power supply unit 40, the pulse RF bias power 77 may be applied to the bias electrode 18 from the RF bias power supply unit 50. The pulse RF source power 73 and the pulse RF bias power 77 may be applied at substantially the same time to the source electrode 16 and the bias electrode 18, respectively. The pulse RF source power 73 and the pulse RF bias power 77 may be generated to have different amplitudes from each other. For example, the amplitude of the pulse RF source power 73 may be greater than the amplitude of the pulse RF bias power 77. In some embodiments, the pulse RF source power 73 and the pulse

RF bias power 77 may be applied with different phases. For example, the pulse RF source power 73 and the pulse RF bias power 77 may be applied in an alternating manner to the source electrode 16 and the bias electrode 18, respectively. The pulse RF source power 73 and the pulse RF bias power 77 may be out of phase with each other, when the pulse RF source power 73 and the pulse RF bias power 77 are applied to the source electrode 16 and the bias electrode 18, respectively. That is, pulse RF bias power 77 may be applied to the bias electrode 18 when the pulse RF source power 73 is not applied to the source electrode 16, as illustrated in FIG. 5. In some embodiments, the pulse RF source power 73 and the pulse RF bias power 77 may be in phase with each other, when the pulse RF source power 73 and the pulse RF bias power 77 are applied to the source electrode 16 and the bias electrode 18, respectively.

Referring to FIG. 1, the plasma 60 may include, for example, radicals 62 and ions 64 that are produced from the reaction gas 32. The radicals 62 and the ions 64 may be used to etch the substrate W, for example, by a chemical reaction. Each of the radicals 62 may contain at least one of atoms constituting the reaction gas 32. For example, each of the radicals 62 may include a hydrogen atom (H). The radicals 62 may have a mean lifetime of about 1 to 100 msec.

Each of the ions 64 may contain a positive ion that is produced from the reaction gas 32. For example, each of the ions 64 may be or include a hydrogen ion (H⁺). The plasma 60 may also contain free electrons (not shown) separated from the ions 64. As a result of recombination between the free electrons and the ions 64, a mean lifetime of the ions 64 may be shorter than that of the radicals 62. The mean lifetime of the ions 64 may range from about 1 μs to about 100 μs.

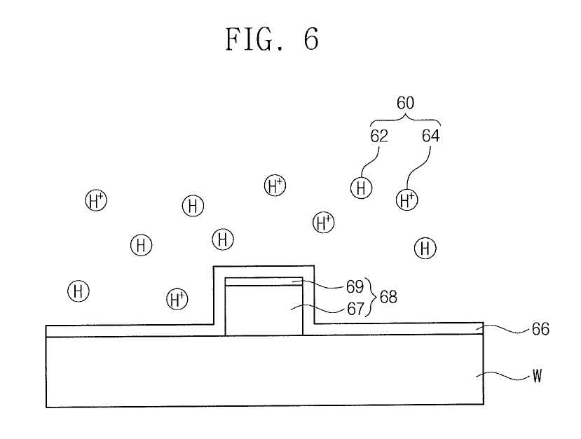

FIG. 6 is a cross-sectional view illustrating the substrate W and the plasma 60 of FIG. 1.

Referring to FIG. 6, the radicals 62, for example, (H), and the ions 64, for example, (H⁺), of the plasma 60 may be used to etch an etch target layer 66 on the substrate W. The etch target layer 66 may be provided on a non-target structure 68. For example, the non-target structure 68 may be disposed between the substrate W and the etch target layer 66.

The etch target layer 66 may be etched or removed by an anisotropic etching process using the radicals 62 and the ions 64 of the plasma 60. Alternatively, the etch target layer 66 may be removed by an isotropic etching process. In some embodiments, the etch target layer 66 may be formed of or include, for example, at least one of anti-reflective coating materials. In some embodiments, the etch target layer 66 may include a mask layer. For example, the etch target layer 66 may be formed of or include at least one of organic materials, for example, photoresist materials.

The non-target structure 68 may be disposed between the substrate W and the etch target layer 66. In some embodiments, the non-target structure 68 may include a lower pattern 67 and an upper pattern 69. The lower pattern 67 may be disposed between the upper pattern 69 and the substrate W. The etch target layer 66 may be formed on an upper surface of the upper pattern 69, along sidewalls of the upper pattern 69 and the lower pattern 67, and along an exposed upper surface of the substrate W. For example, the lower pattern 67 may include a channel or active pattern of a fin field effect transistor (Fin-FET). The lower pattern 67 may include, for example, silicon germanium (SiGe). The upper pattern 69 may be disposed on the lower pattern 67. For example, the upper pattern 69 may include a sacrificial protection layer. In some embodiments, the upper pattern 69 may include, for example, silicon nitride (Si₃N₄). The upper pattern 69 may protect a top surface of the lower pattern 67 from the radicals 62 and the ions 64, when an etching process is performed on the etch target layer 66. Although not illustrated, the upper pattern 69 may be etched or removed by, for example, an isotropic etching method. For example, the upper pattern 69 may be etched or removed by a wet etching method. After the etching process, a gate insulating layer and a gate electrode may be formed on the lower pattern 67. The lower pattern 67 and the gate electrode may be used as elements of the Fin FET. In an embodiment in which a top surface of the lower pattern 67 is damaged, the lower pattern 67 may lead to operation failure of the Fin FET, for example, in a switching operation.

Referring to FIGS. 1 and 6, the end-point detector 34 may be provided on or near the housing 12 of the chamber unit 10. The end-point detector 34 may be configured to detect an end point of an etching process to be performed on the etch target layer 66. For example, the end-point detector 34 may include a photo diode or a light sensor. The end-point detector 34 may be configured to sense a change in color or spectrum of light emitted from the chamber unit 10, in which the etch target layer 66 and the non-target structure 68 are etched in the plasma 60. The end-point detector 35 may be configured to detect an end point of the etching process, hereinafter, an end point. For example, in an embodiment in which the etch target layer 66 and the non-target structure 68 are sequentially etched, the color of the plasma 60 may be changed from yellow to blue. In some embodiments, the color of plasma 60 may be changed from red to green or from blue to red. The end point may be determined, based on information on the change in color of the plasma 60. If an etching rate in the etching process is precisely controlled, it is possible to prevent or suppress the upper pattern 69 and the lower pattern 67 from being damaged by the etching process.

Referring to FIGS. 1, 4, 5, and 6, in the embodiment in which the CW plasma is used to etch the etch target layer 66, an etching rate of the etch target layer 66 may be in proportion to the CW RF source power 71 and the CW RF bias power 75. In the embodiment in which the pulse plasma is used to etch the etch target layer 66, an etching rate of the etch target layer 66 may be in proportion to the pulse RF source power 73 and the pulse RF bias power 77. The CW RF bias power 75 and the pulse RF bias power 77 may increase or decrease in proportion to the CW RF source power 71 and the pulse RF source power 73, respectively. In some embodiments, the etching rate of the etch target layer 66 may be expressed in terms of a ratio, or proportional expression, between the CW RF source power 71 and the pulse RF source power 73. That is, the etching rate of the etch target layer 66 may be calculated from the proportional expression, in which the CW RF bias power 75 and the pulse RF bias power 77 are neglected. If the etching rate of the etch target layer 66 under the CW plasma generated by the CW RF source power 71 is known, process conditions for the etching process using the pulse RF source power 73 may be determined. The CW RF source power 71 and the pulse RF source power 73 may be controlled by the RF source power supply unit 40 and the RF bias power supply unit 50, resulting in controlling the etching rate of the etch target layer 66.

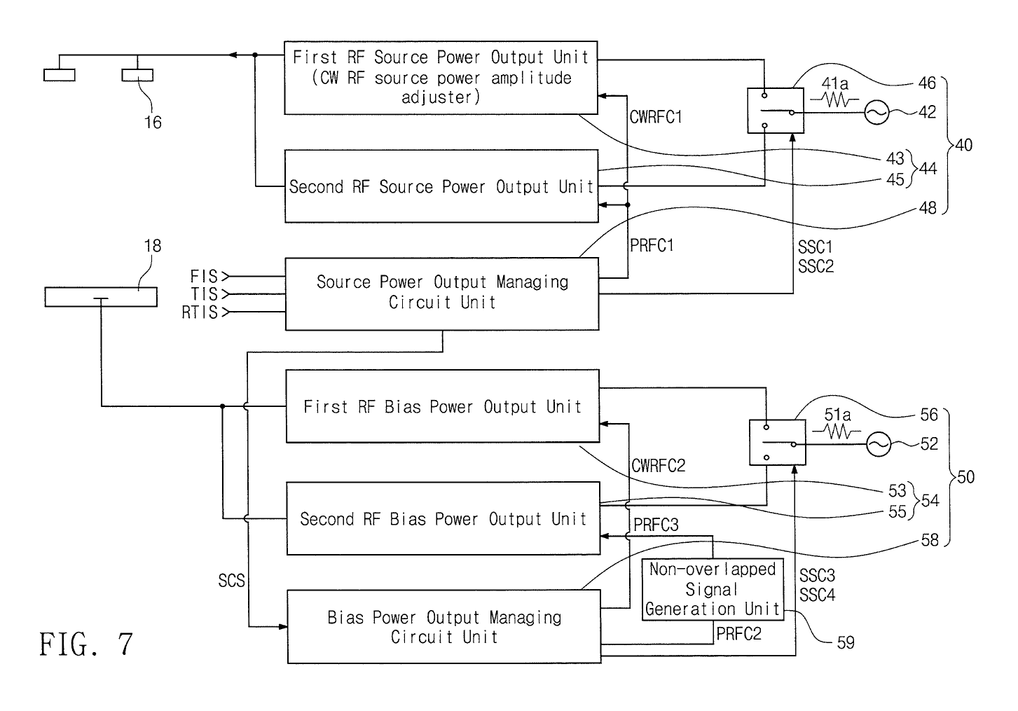

FIG. 7 is a block diagram illustrating the RF source power supply unit 4Q and the RF bias power supply unit 50 of FIG. 1 according to some embodiments of the inventive concepts.

Referring to FIG. 7, the RF source power supply unit 40 may include, for example, a source power generation unit 42, a source power output unit 44, a source power mode selection unit 46, and a source power output managing unit 48.

The source power generation unit 42 may be configured to generate a preliminary RF source power 41a . The source power generation unit 42 may receive a power from an external device.

The source power output unit 44 may be connected between the source electrode 16, or the plurality of source electrodes 16, and the source power generation unit 42. In some embodiments, the source power output unit 44 may include a first RF source power output unit 43 and a second RF source power output unit 45.

The first RF source power output unit 43 may be configured to convert the preliminary RF source power 41a to the CW RF source power 71 in response to a first output control signal CWRFC1 from the source power output managing unit 48 and, then, output the CW RF source power 71 to the source electrode 16. For example, the first RF source power output unit 43 may include a CW RF source power amplitude adjuster.

The second RF source power output unit 45 may be configured to convert the preliminary RF source power 41a to the pulse RF source power 73 in response to a second output control signal PRFC1 from the source power output managing unit 48 and, then, output the pulse RF source power 73 to the source electrode 16.

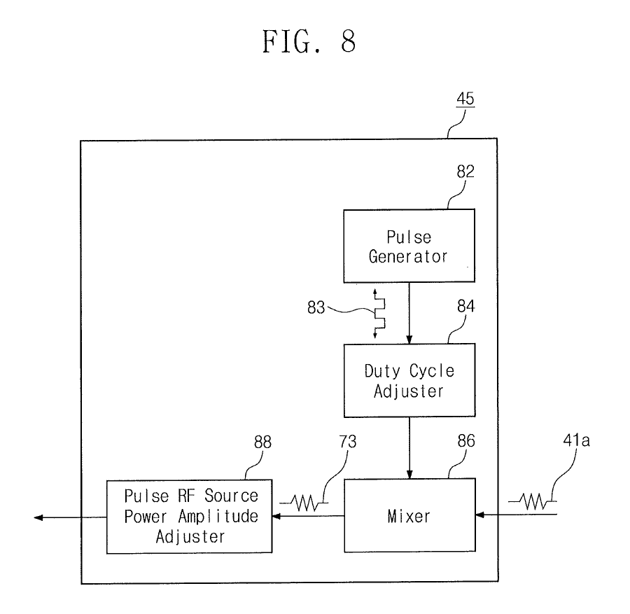

FIG. 8 is a block diagram illustrating the second RF source power output unit 45 of FIG. 7 according to some embodiments of the inventive concepts.

Referring to FIG. 8, the second RF source power output unit 45 may include a pulse generator 82, a duty cycle adjuster 84, a mixer 86, and a pulse RF source power amplitude adjuster 88. The pulse generator 82 may be configured to generate a pulse signal 83. The pulse generator 82 may also be configured to adjust a pulsing frequency of the pulse signal 83. The pulse generator 82 may provide the pulse signal 83 to the duty cycle adjuster 84. The duty cycle adjuster 84 may be configured to adjust the duty cycle of the pulse signal 83 from the pulse generator 82 and provide the pulse signal with the adjusted duty cycle to the mixer 86. The mixer 86 may be configured to mix the pulse signal 83 from the duty cycle adjuster 84 with the preliminary RF source power 41a and, then, output the mixed result as the pulse RF source power 73. The pulse RF source power amplitude adjuster 88 may receive the pulse RF source power 73 from the mixer 86 and may be configured to adjust an amplitude B of the pulse RF source power 73.

Referring to FIG. 7, the source power mode selection unit 46 may be connected between the source power output unit 44 and the source power generation unit 42. The source power mode selection unit 46 may include, for example, a switch for switching between the first RF source power output unit 43 and the second RF source power output unit 45 in response to the first and second selection control signals SSC1 and SSC2. The source power mode selection unit 46 may connect the source power generation unit 42 to the first RF source power output unit 43 in response to the first selection control signal SSC1 from the source power output managing unit 48. In some embodiments, the source power mode selection unit 46 may connect the source power generation unit 42 to the second RF source power output unit 45 in response to the second selection control signal SSC2 from the source power output managing unit 48.

The source power output managing unit 48 may receive a feedback input signal FIS, a thickness input signal TIS containing information on a thickness of the etch target layer 66, and a recombination time input signal RTIS containing information on a recombination time of the reaction gas 32. The feedback input signal FIS may contain information on the end point, which is transmitted from, for example, the end-point detector 34. The thickness input signal TIS and the recombination time input signal RTIS may be provided from, for example, an external input device and/or a database. The source power output managing unit 48 may be configured to calculate the etching rate of the etch target layer 66 from the feedback input signal FIS and the thickness input signal TIS. The source power output managing unit 48 may also be configured to calculate a pulsing frequency of the pulse RF source power 73 from the recombination time input signal RTIS. The source power output managing unit 48 may control the first and second RF source power output units 43 and 45 and the source power mode selection unit 46 based on the calculated etching rate and pulsing frequency. The source power output managing unit 48 may output the first output control signal CWRFC1 and a second output control signal PRFC1 to the first source power output unit 43 and the second source power output unit 45, respectively. The source power output managing unit 48 may output the first selection control signal SSC1 and the second selection control signal SSC2 to the source power mode selection unit 46.

Referring to FIG. 7, the RF bias power supply unit 50 may include a bias power generation unit 52, a bias power output unit 54, a bias power mode selection unit 56, a bias power output managing unit 58, and a non-overlapped signal generation unit 59.

The bias power generation unit 52 may be configured to generate a preliminary RF bias power 51a . The bias power generation unit 52 may receive a power from an external device.

The bias power output unit 54 may be connected between the bias power generation unit 52 and the bias electrode 18. In some embodiments, the bias power output unit 54 may include first and second RF bias power output units 53 and 55.

The first RF bias power output unit 53 may be configured to convert the preliminary RF bias power 51a to the CW RF bias power 75 in response to the third output control signal CWRFC2 from the bias power output managing unit 58 and, then, output the CW RF bias power 75 to the bias electrode 18.

The second RF bias power output unit 55 may be configured to convert the preliminary RF bias power 51a to the pulse RF bias power 77 in response to a sixth output control signal PRFC3 from the bias power output managing unit 58 and, then, output the pulse RF bias power 77 to the bias electrode 18.

The bias power mode selection unit 56 may be connected between the bias power output unit 54 and the bias power generation unit 52. The bias power mode selection unit 56 may include, for example, a switch for switching between the first RF bias power output unit 53 and the second RF bias power output unit 55 in response to the third and fourth selection control signals SSC3 and SSC4. The bias power mode selection unit 56 may connect the bias power generation unit 52 to the first RF bias power output unit 53 in response to the third selection control signal SSC3 from the bias power output managing unit 58. In some embodiments, the bias power mode selection unit 56 may connect the bias power generation unit 52 to the second RF bias power output unit 55 in response to the fourth selection control signal SSC4 from the bias power output managing unit 58.

The bias power output managing unit 58 may be controlled by the synchronizing control signal SCS, which is generated by and transmitted from the source power output managing unit 48 to the bias power output managing unit 58. The bias power output managing unit 58 may control the first RF bias power output unit 53, the second RF bias power output unit 55, and the bias power mode selection unit 56. The bias power output managing unit 58 may output the third output control signal CWRFC2 and a fourth output control signal PRFC2 to the first RF bias power output unit 53 and the second RF bias power output unit 55, respectively. The bias power output managing unit 58 may output the third selection control signal SSC3 and the fourth selection control signal SSC4 to the bias power mode selection unit 56.

The non-overlapped signal generation unit 59 may be connected between the bias power output managing unit 58 and the second bias power output unit 55. The non-overlapped signal generation unit 59 may be configured to invert the phase of the pulse RF bias power 77 such that the pulse RF bias power 77 has a phase that is opposite to that of the pulse RF source power 73, that is, such that the pulse RF bias power 77 does not overlap with the pulse RF source power 73. For example, the non-overlapped signal generation unit 59 may include an inverter. In the embodiment in which the pulsing frequency of the fourth output control signal PRFC2 is the same as that of the second output control signal PRFC1, the non-overlapped signal generation unit 59 may invert the fourth output control signal PRFC2. The second RF bias power output unit 55 may output the pulse RF bias power 77 in response to the inverted fourth output control signal PRFC2. The phase of the pulse RF bias power 77 may be opposite to that of the pulse RF source power 73.

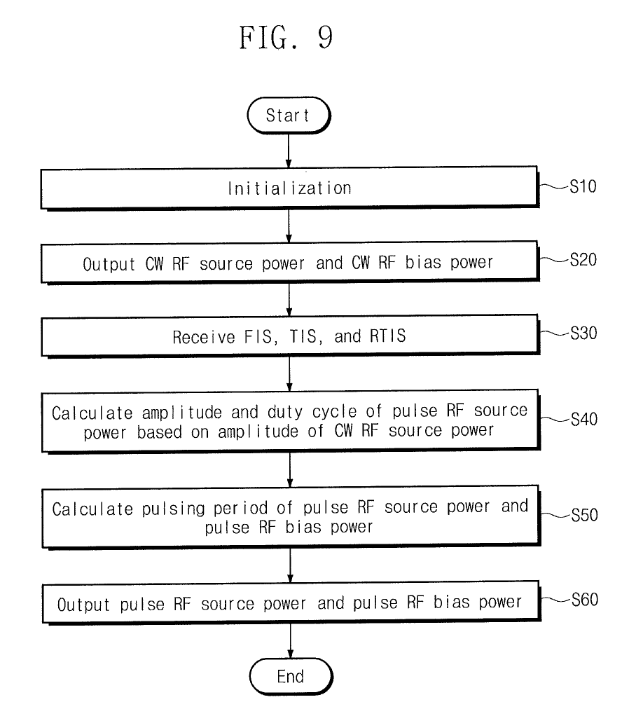

FIG. 9 is a flow chart illustrating a plasma processing method, which may be performed using the source power managing unit 48 of FIG. 7 according to some embodiments of the inventive concepts.

Referring to FIGS. 1 and 6 to 9, after an initialization (S10), the source power output managing unit 48 may output the first output control signal CWRFC1 and the first selection control signal SSC1 to the first RF source power output unit 43 and the source power mode selection unit 46, respectively. The first RF source power output unit 43 may output the CW RF source power 71 to the source electrode 16 (S20). Moreover, the bias power output managing unit 58 may output the third output control signal CWRFC2 and the third selection control signal SSC3 to the first RF bias power output unit 53 and the bias power mode selection unit 56, respectively. The first RF bias power output unit 53 may output the CW RF bias power 75 to the bias electrode 18 (S20). The source power output managing unit 48 may store information on the amplitude A of the CW RF source power 71 in, for example, a database and/or a memory.

The etch target layer 66 may be etched by the reaction with the CW plasma 60 generated by the CW RF source power 71. In some embodiments, the etch target layer 66 may be formed on a test substrate serving as the substrate W. The end-point detector 34 may be configured to detect an end point of an etching process, which is performed on the etch target layer 66 using the CW plasma 60. The end point may be changed depending on various factors associated with the plasma 60, the reaction gas 32, and an internal environment of the housing 12. For example, even if there is no change associated with the plasma 60 and the reaction gas 32, the end point may vary depending on a cumulative usage time of the housing 12. For example, the larger the cumulative usage time of the housing 12, the later the end point. The end-point detector 34 may output the feedback input signal FIS containing information about the end point to the source power output managing unit 48. In some embodiments, the feedback input signal FIS may be provided to the source power output managing unit 48 from, for example, an external input device and/or a database.

Next, the source power output managing unit 48 may receive the feedback input signal FIS, the thickness input signal TIS containing information on a thickness of the etch target layer 66, and the recombination time input signal RTIS containing information on a recombination time of the reaction gas 32 (S30). The source power output managing unit 48 may calculate the etching rate of the etch target layer 66 under the CW plasma 60, from the feedback input signal FIS and the thickness input signal TIS. The etching rate of the etch target layer 66 under the CW plasma may contain information on the internal environment of the housing 12. That is, the etching rate may reflect the process condition for the etching process performed in the housing 12.

The source power output managing unit 48 may request and receive information on the amplitude A of the CW RF source power 71 from a database and/or a memory. The source power output managing unit 48 may calculate the amplitude B and the duty cycle of the pulse RF source power 73 from the obtained information on the amplitude A of the CW RF source power 71 (S40).

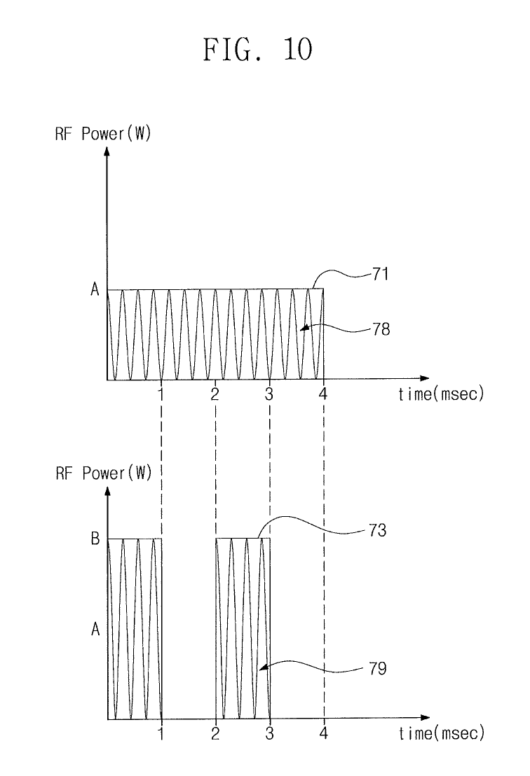

FIG. 10 is graphs illustrating energies 78 and 79 of the CW RF source power 71 and the pulse RF source power 73, respectively, allowing the etch target layer 66 to be etched at the same etching rate. Horizontal axes of the graphs of FIG. 10 represent a process time (in msec), and vertical axes of the graphs of FIG. 10 represent an intensity or amplitude of an RF power (in W).

Referring to FIG. 10, the energy 78 of the CW RF source power 71 may be equal to the energy 79 of the pulse RF source power 73.

The energy 78 of the CW RF source power 71 may be given by a product of the amplitude A and the supply time of the CW RF source power 71. The source power output managing unit 48 may calculate the energy 78 of the CW RF source power 71 from the supply time and the amplitude A of the CW RF source power 71.

The energy 79 of the pulse RF source power 73 may be given by a product of the amplitude B, the duty cycle, and the supply time of the pulse RF source power 73. In some embodiments, the amplitude B of the pulse RF source power 73 may be greater than the amplitude A of the CW RF source power 71. The duty cycle may be defined as a ratio of a duration time to a total supply time of the pulse RF source power 73. A total supply time of the CW RF source power 71 may be the same as that of the pulse RF source power 73, and in this embodiment, the amplitude A of the CW RF source power 71 may correspond to a product between the amplitude B and the duty cycle of the pulse RF source power 73. In some embodiments, the duty cycle of the pulse RF source power 73 may range from, for example, 0.1 to 0.9. In the embodiment in which the duty cycle of the pulse RF source power 73 is 50%, the amplitude B of the pulse RF source power 73 may be two times the amplitude A of the CW RF source power 71. In some embodiments, the source power managing unit 48 may determine an amplitude and/or a duty cycle for the pulse RF source power 73, based on the obtained information on the amplitude A of the CW RF source power 71 and the plasma 60 generated using the CW RF source power 71.

Referring to FIG. 9, next, the source power managing unit 48 may calculate the pulsing frequencies of the pulse RF source power 73 and the pulse RF bias power 77, from the recombination time input signal RTIS (S50). The recombination time input signal RTIS may be produced to contain information on lifetimes of the radicals 62 and the ions 64.

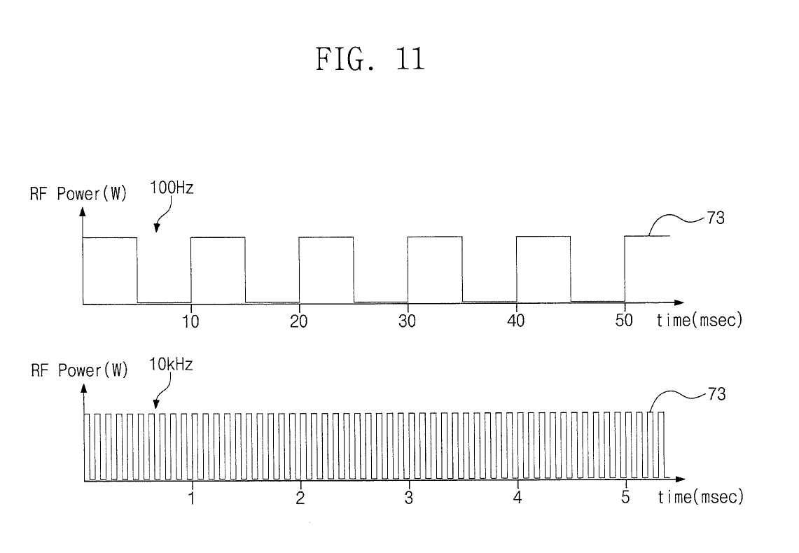

FIG. 11 is graphs illustrating an example of a pulsing frequency of the pulse RF source power 73. Horizontal axes of the graphs of FIG. 11 represent a process time (in msec), and vertical axes of the graphs of FIG. 11 represent an intensity or amplitude of an RF power (in W).

Referring to FIGS. 6 to 9, and 11, the pulse RF source power 73 may have a pulsing frequency ranging from, for example, about 100 Hz to 10 KHz. Likewise, the pulse RF bias power 77 may have a pulsing frequency ranging from, for example, about 100 Hz to 10 KHz. In some embodiments, the pulse RF source power 73 may have a pulsing cycle that is shorter than the lifetime of the radicals 62. By contrast, the pulsing cycle of the pulse RF source power 73 may be longer than the lifetime of the ions 64. The pulsing cycle of the pulse RF source power 73 may range from, for example, about 0.1 msec to about 10 msec. A pulsing frequency may be the reciprocal of the pulsing cycle. That is, the pulsing frequency may range from about 100 Hz to about 10 KHz.

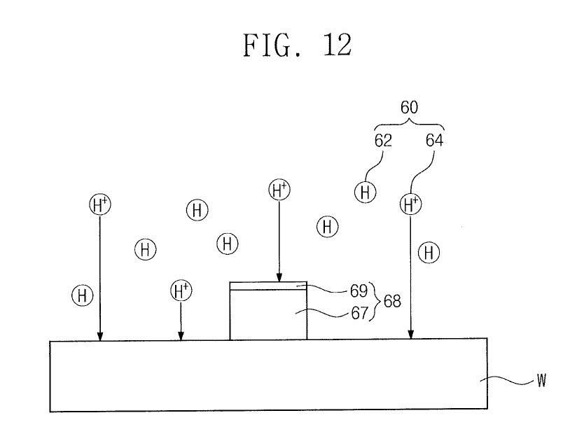

FIG. 12 is a cross-sectional view illustrating a bombardment phenomenon of ions 64.

Referring to FIG. 12, in the embodiment in which a period of the pulse RF bias power 77 or the pulse RF source power 73 is shorter than the lifetime of the ions 64, the ions 64 may collide with top surfaces of the substrate W and the upper pattern 69. The ions 64 may be accelerated toward the substrate W by the pulse RF bias power 77, and thus, the top surfaces of the substrate W and the upper pattern 69 may be damaged by the bombardment phenomenon of the ions 64. By contrast, in the embodiment in which the period of the pulse RF bias power 77 and/or the pulse RF source power 73 is longer than the lifetime of the ions 64, none of the ions 64 may reach the substrate W. Accordingly, the bombardment phenomenon of the ions 64 may be prevented or suppressed. That is, in the plasma processing method according to some embodiments of the inventive concepts, the substrate W and the upper pattern 69 may be prevented from being damaged by the bombardment phenomenon of the ions 64.

Referring again to FIGS. 7, 8 and 9, the source pulse managing unit 48 and the bias pulse managing unit 58 may output the pulse RF source power 73 and the pulse RF bias power 77 to the source electrode 16 and the bias electrode 18, respectively (S60). An etching process may be performed using the pulse plasma generated by the pulse RF source power 73 and the pulse RF bias power 77. The etching rate of the pulse plasma may be substantially the same as that of the CW plasma.

FIG. 13 is a graph illustrating a relationship between an etching rate of the etch target layer 66 and the pulse RF source power 73 of FIG. 10. Horizontal axes of the graph of FIG. 13 represent an etching rate of an etch target layer (in Å/min), and vertical axes of the graph of FIG. 13 represent a pulse RF source power (in W).

Referring to FIG. 13, the etching rate of the etch target layer 66 was proportional to the pulse RF source power 73. The higher the pulse RF source power 73, the higher the etching rate of the etch target layer 66. For example, when the pulse RF source power 73 of about 1000 W was used to generate the plasma 60, the etching rate of the etch target layer 66 was about 125 Å/min. For example, when the pulse RF source power 73 of about 2000 W was used to generate the plasma 60, the etching rate of the etch target layer 66 was about 200 Å/min, For example, when the pulse RF source power 73 was about 4000 W, the etching rate of the etch target layer 66 was about 350 Å/min.

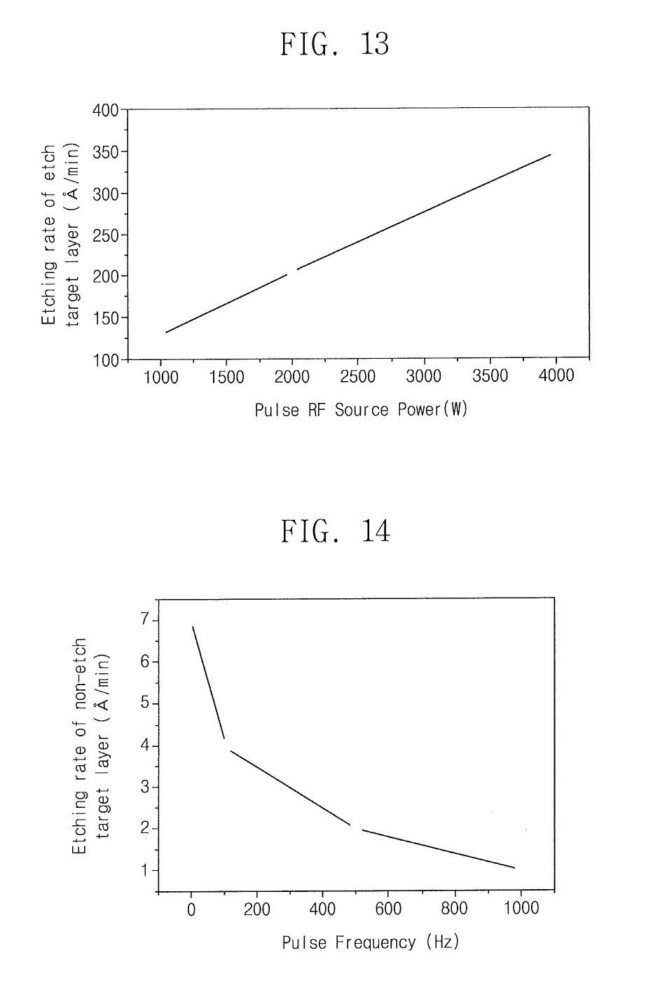

FIG. 14 is a graph illustrating a relationship between an etching rate of the non-target structure 68 and a pulsing frequency of the pulse RF bias power 77 of FIG. 11. Horizontal axes of the graph of FIG. 14 represent an etching rate of an etch target layer (in Å/min), and vertical axes of the graph of FIG. 13 represent a pulse frequency (in Hz).

Referring to FIG. 14, the pulsing frequency of the pulse RF bias power 77 was inversely proportional to the etching rate of the non-target structure 68. The higher the pulsing frequency of the pulse RF bias power 77, the lower the etching rate of the non-target structure 68. That is, the increase in the pulsing frequency of the pulse RF bias power 77 led to a reduction of the bombardment phenomenon on the non-target structure 68. For example, when the pulse RF bias power 77 had a pulsing frequency of 0 Hz, an etching rate of the non-target structure 68 was about 7 Å/min. For example, when the pulse RF bias power 77 of 0 Hz was used, the non-target structure 68 was damaged by the bombardment phenomenon of the ions 64. The pulse RF bias power 77 of 0 Hz may correspond to the CW RF bias power 75. For example, when the pulsing frequency was about 100 Hz, an etching rate of the non-target structure 68 was about 4 Å/min. When the pulsing frequency was about 500 Hz, an etching rate of the non-target structure 68 was about 2 Å/min. When the pulsing frequency was about 1000 Hz, an etching rate of the non-target structure 68 was about 1 Å/min. The pulsing cycle may be about 1 msec. When the pulsing cycle is shorter than the lifetime of the radical 62 and is longer than the lifetime of the ions 64, the damage of the non-target structure 68 may be minimized. Moreover, the bombardment phenomenon of the ions 64 damaging substrate W and the upper pattern 69 may also be minimized,

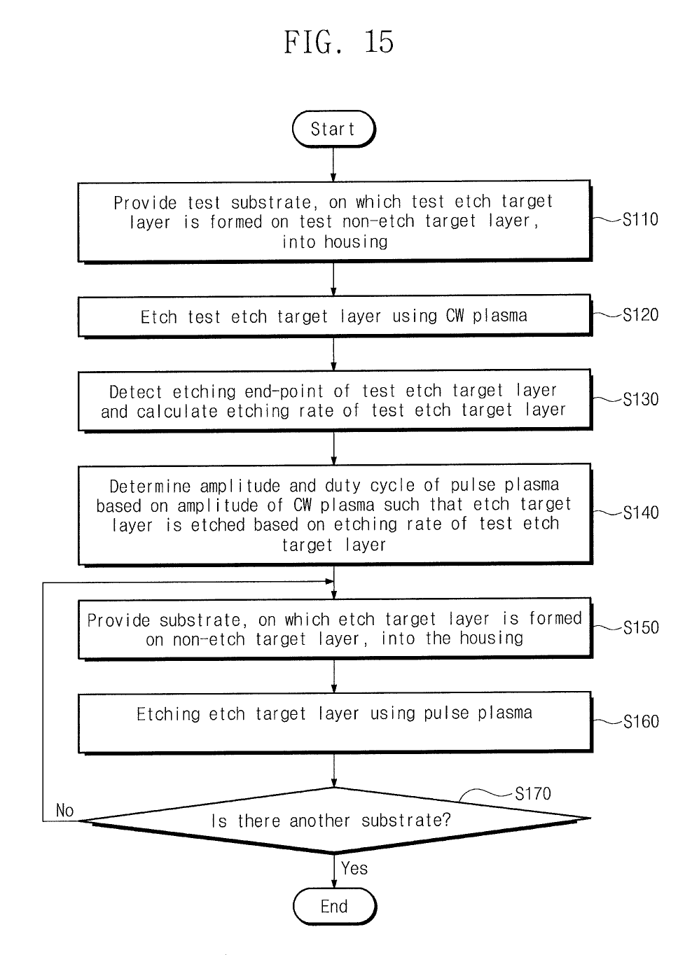

FIG. 15 is a flow chart illustrating of a plasma etching method, which may be performed using the plasma system 100 of FIG. 1 according to some embodiments of the inventive concepts.

Referring to FIGS. 1, 6, and 15, a test substrate, on which a test non-target structure and a test etch target layer are sequentially stacked, may be loaded on the electrostatic chuck 14 in the housing 12 (S110). That is, the test target layer may be formed on the test non-etch target layer. The test non-target structure, the test etch target layer, and the test substrate may correspond to the non-target structure 68, the etch target layer 66, and the substrate W, respectively.

Referring to FIGS. 1, 7 and 15, the CW plasma may be generated within a region on or over the test etch target layer and may be used to etch the test etch target layer (S120). The CW plasma may be induced by the RF source power 41 and the RF bias power 51 that are applied to the first RF source power output unit 43 and the first RF bias power output unit 53, respectively. The CW plasma may be generated from a reaction gas, for example, a hydrogen gas, supplied onto the test substrate, for example, reaction gas 32.

The etching process using the CW plasma may be performed on the test etch target layer. An end point of the etching process may be detected by the end-point detector 34. The source power output managing unit 48 may calculate the etching rate of the test etch target layer from information on the end point, for example, feedback input signal FIS (S130). Thereafter, the test substrate may be unloaded from the housing 12.

Referring to FIGS. 6, 7, 10, and 15, in the source power output managing unit 48, the amplitude B and the duty cycle of the pulse plasma may be determined based on information on the amplitude A of the CW plasma (S140), allowing the etch target layer 66 to be etched at the etching rate of the test etch target layer. Moreover, the source power output managing unit 48 may determine the pulsing cycle of the pulse plasma. The pulsing cycle may be shorter than the lifetime of the radicals 62 in the plasma 60 and may be longer than the lifetime of the ions 64.

Referring to FIGS. 1, 6, and 15, the substrate W, on which the non-target structure 68 and the etch target layer 66 are sequentially stacked, may be loaded on the electrostatic chuck 14 in the housing 12 (S150). That is, the non-test substrate may be loaded on the electrostatic chuck 14 in the housing 12.

Referring to FIGS. 1, 6, 7 and 15, the second RF source power output unit 45 and the second RF bias power output unit 55 may be controlled to generate the pulse plasma from the reaction gas 32 supplied on the etch target layer 66 and to etch the etch target layer 66 (S160). In some embodiments, the etch target layer 66 may be etched at the same etching rate as that of the test etch target layer. The source power output managing unit 48 may adjust the pulsing cycle of the pulse plasma such that the pulsing cycle of the pulse plasma is shorter than the lifetime of the radicals 62 in the plasma 60 and is longer than the lifetime of the ions 64. The end-point detector 34 may detect an end point of the etching process on the etch target layer 66. The source power output managing unit 48 may stop to generate the pulse plasma. Thereafter, the substrate W may be unloaded from the housing 12.

Next, the source power output managing unit 48 may determine whether there is another substrate, for which the etching process is required (S170). If there is another substrate in which the etch target layer 66 will be removed, steps S150 to S170 may be repeated. Otherwise, the source power output managing unit 48 may end the etching process using the pulse plasma.

In the plasma system according to some embodiments of the inventive concepts, an amplitude of a continuous wave RF source power may be expressed in terms of a product of an amplitude and a duty cycle of a pulse RF source power. Accordingly, the amplitude and the duty cycle of the pulse RF source power may be controlled to realize the same etching rate as that of the continuous wave plasma. For example, a pulsing frequency of the pulse plasma may be controlled to be greater than the reciprocal of a lifetime of radicals and smaller than the reciprocal of a lifetime of ions. Accordingly, most of the ions may be recombined with electrons, and, thus, the ions may be prevented from reaching a non-target structure formed on a substrate. That is, damage to the non-target layer may be prevented, suppressed or minimized.

While example embodiments of the inventive concepts have been particularly shown and described, it will be understood by one of ordinary skill in the art that variations in form and detail may be made therein without departing from the spirit and scope of the attached claims.

1. A plasma system, comprising:
a source electrode configured to generate plasma in a housing;
a radio frequency (RF) source power generation unit configured to generate an RF source power to be provided to the source electrode;
an RF source power output unit connected between the source electrode and the RF source power generation unit, the RF source power output unit configured to convert the RF source power to one of a first and second RF source power in response to a first output control signal, and to output the one of the first and second RF source power to the source electrode; and
a source power output managing unit configured to determine an amplitude and a duty cycle of the second RF source power based on information on an amplitude of the first RF source power and to apply the first output control signal, which is used to output the second RF source power according to the determined amplitude and the determined duty cycle, to the RF source power output unit.

2. The plasma system of claim 1, wherein the RF source power output unit comprises:
a first RF source power output unit configured to convert the RF source power to the first RF source power and to apply the first RF source power to the source electrode; and
a second RF source power output unit configured to convert the RF source power to the second RF source power and to apply the second RF source power to the source electrode, and
wherein the amplitude of the second RF source power is greater than the amplitude of the first RF source power.

3. The plasma system of claim 2, further comprising:
a source power mode selection unit configured to selectively connect the source RF generation unit to the one of the first and second RF source power output unit in response to a first selection control signal from the source power output managing unit.

4. The plasma system of claim 2, wherein the first RF source power output unit comprises a continuous wave RF source power amplitude adjuster configured to adjust an amplitude of the RF source power and to output the RF source power with the adjusted amplitude as the first RF source power.

5. The plasma system of claim 2, wherein the second RF source power output unit comprises:
a pulse generator configured to generate a pulse signal;
a duty cycle adjuster configured to adjust a duty cycle of the pulse signal; and
a mixer configured to mix the RE source power with the pulse signal and to output the mixed result as the second RF source power.

6. The plasma system of claim 2, wherein the second RF source power output unit comprises:
a pulse RF source power amplitude adjuster configured to adjust the amplitude of the second RF source power.

7. The plasma system of claim 1, further comprising:
a bias electrode disposed in the housing to face the source electrode;
an RF bias power generation unit configured to generate an RF bias power to be provided to the bias electrode;
an RF bias power output unit connected between the RF bias power generation unit and the bias electrode, the RE bias power output unit configured to convert the RF bias power to one of a first and second RF bias power in response to a third control signal and to output the one of the first and second RF bias power to the bias electrode; and
a bias power output managing unit configured to apply the third control signal to the RF bias power output unit in response to a fourth control signal from the source power output managing unit, the third control signal being used to output the one of the first and second RF bias power corresponding to the one of the first and second RF source power, respectively.

8. The plasma system of claim 7, wherein the RF bias power output unit comprises:
a first RF bias power output unit configured to convert the RF bias power to the first RF bias power and to apply the first RF bias power to the bias electrode; and
a second RF bias power output unit configured to convert the RF bias power to the second RF bias power and to apply the second RF bias power to the bias electrode

9. The plasma system of claim 8, further comprising:
a bias power mode selection unit configured to connect the bias RF generation unit to the one of the first and second RF bias power output unit in response to a fifth control signal from the bias power output managing unit.

10. The plasma system of claim 8, further comprising:
a non-overlapped signal generation unit connected between the bias power output managing unit and the second RF bias power output unit, the non-overlapped signal generation unit configured to apply a sixth control signal to the second RF bias power output unit in response to the third control signal, the sixth control signal used to invert a phase of the second RF bias power to a phase opposite to that of the second RF source power.

11. A plasma system, comprising:
a source electrode configured to generate plasma in a housing;
an RF power generation unit configured to generate an RF source power to be provided to the source electrode;
a power mode selection unit connected between the RF power generation unit and the source electrode, the power mode selection unit configured to select whether to convert the RF source power to one of a first and second RF source power in response to a first control signal;
an RF source power output unit connected between the power mode selection unit and the source electrode, the RF source power output unit configured to convert the RF source power to the one of the first and second RF source power and to output the one of the first and second RF source power to the source electrode in response to a second control signal; and
a source power output managing unit configured to apply, to the power mode selection unit, the first control signal for determining the one of the first and second RF source power to be applied to the source electrode, to determine an amplitude and a duty cycle of the second RF source power based on information on an amplitude of the first RF source power, and to apply, to the RF source power output unit, the second control signal for outputting the second RF source power based on the determined amplitude and the determined duty cycle.

12. The plasma system of claim 11, wherein the RF source power output unit comprises:
a first RF source power output unit configured to convert the RF source power to the first RF source power and to apply the first RF source power to the source electrode;
and a second RF source power output unit configured to convert the RF source power to the second RF source power and to apply the second RF source power to the source electrode, and
wherein the power mode selection unit selectively connects the one of the first and second RF source power output unit to an RF source power generation unit.

13. The plasma system of claim 12, wherein the first RF source power output unit comprises a continuous wave RF power amplitude adjuster configured to adjust the amplitude of the first RF source power.

14. The plasma system of claim 12, wherein the second RF source power output unit comprises:
a pulse generator configured to generate a pulse signal;
a duty cycle adjuster configured to adjust a duty cycle of the pulse signal;
a mixer configured to mix the RF source power and the pulse signal and to output the mixed result as the second RF source power; and
a pulse RF source power amplitude adjuster configured to adjust the amplitude of the second RF source power.

15. The plasma system of claim 11, further comprising:
a bias electrode disposed in the housing;
an RF bias power generation unit configured to generate an RF bias power to be provided to the bias electrode;
an RF bias power output unit connected between the RF bias power generation unit and the bias electrode, the RF bias power output unit configured to convert the RF bias power to one of a first and second RF bias power in response to a third control signal and to output the one of the first and second RF bias power to the bias electrode; and
a bias power output managing unit configured to apply, to the RF bias power output unit, the third control signal for outputting the one of the first and second RF bias power corresponding to the one of the first and second RF source power in response to a fourth control signal from the source power output managing unit.

16-20. (canceled)

21. A plasma system, comprising:
a chamber unit comprising a housing, a source electrode on the housing, and a bias electrode on an inner, bottom surface of the housing;
a reaction gas supply unit configured to supply a reaction gas into the housing; and
an RF source power supply unit connected to the source electrode, the RF source power supply unit configured to apply an RF source power to the reaction gas to generate plasma in the housing;
wherein the RF source power supply unit comprises:
an RF source power generation unit configured to generate the RF source power;
an RF source power output unit connected between the source electrode and the RF source power generation unit, the RF source power output unit configured to convert the RF source power to one of a first and second RF source power in response to a first output control signal and to output the one of the first and second RF source power to the source electrode, respectively; and
a source power output managing unit configured to determine an amplitude and a duty cycle of the second RF source power based on information on an amplitude of the first RF source power and to apply the first output control signal, which is used to output the second RF source power according to the determined amplitude and the determined duty cycle, to the RF source power output unit.

22. The plasma system of claim 21, further comprising:
an end-point detector configured to detect an end point of an etching process, in which a layer is etched using the plasma,
wherein the source power output managing unit receives a feedback input signal and a layer thickness signal from the end-point detector and calculates an etching rate of the layer, and the feedback input signal contains information on the end point of the etching process and the layer thickness signal contains information on a thickness of the layer.

23. The plasma system of claim 21, wherein the plasma comprises a radical and an ion, and
wherein the source power output managing unit determines a pulsing cycle of the second RF source power such that the pulsing cycle is longer than a lifetime of the ion.

24. The plasma system of claim 23, wherein the source power output managing unit determines the pulsing cycle of the second RF source power such that the pulsing cycle is shorter than a lifetime of the radical.

25. The plasma system of claim 21, further comprising:
an RF bias power supply unit controlled by the source power output managing unit, the RF bias power supply unit configured to supply an RF bias power to the bias electrode.

26-45. (canceled)
